(19) United States
(12) Patent Application Publication
(10) Pub. No.: US 2015/0047698 A1
(43) Pub. Date: Feb. 19, 2015

(54) PROTECTIVE COATINGS FOR PHOTOVOLTAIC CELLS

(71) Applicant: NUVOSUN, INC., Milpitas, CA (US)

(72) Inventor: Dennis R. Hollars, San Jose, CA (US)

(21) Appl. No.: 14/371,494

(22) PCT Filed: Jan. 16, 2013
(86) PCT No.: PCT/US2013/021770

§ 371 Date: Jul. 10, 2014

Related U.S. Application Data
(60) Provisional application No. 61/588,611, filed on Jan. 19, 2012.

(51) Int. Cl. H01L 31/0216; H01L 31/18; H01L 31/0749

(52) U.S. Cl. CPC H01L 31/02167; H01L 31/0749; H01L 31/18
USPC 136/256; 438/94

(57) ABSTRACT

A photovoltaic cell comprises a protective layer, a substrate adjacent to the protective layer, and a barrier layer adjacent to the substrate. The protective layer can comprise niobium, or a metal carbide, metal boride, metal nitride, or metal silicide. The barrier layer can comprise an electrically conductive material. The photovoltaic cell further comprises an absorber layer adjacent to the barrier layer. The absorber layer in some cases comprises copper indium gallium di-selenide (CIGS). The photovoltaic cell further comprises an optically transparent window layer adjacent to the absorber layer, and an electrically non-conductive aluminum zinc oxide (AZO) layer adjacent to the window layer. A transparent oxide layer is disposed adjacent to the AZO layer.

### CROSS-REFERENCE

This application claims priority to U.S. Provisional Patent Application No. 61/588,611, filed Jan. 19, 2012, which is entirely incorporated herein by reference.

### BACKGROUND

Thin film solar (or photovoltaic) cells utilizing copper indium gallium diselenide (CIGS), copper indium diselenide (CIS), cadmium telluride and all of their related compounds which use selenium, sulfur, and tellurium typically go through a high temperature (approximately 400° C. to 600° C.) growth or annealing phase to form the material. When these materials are deposited on flexible metallic foils—e.g., stainless steel—any exposed area of the substrate can be rapidly attacked by the selenium, sulfur or tellurium in the hot environment. If left unprotected, reaction products such as iron selenides, sulfides, or tellurides may form on the stainless steel. These compounds are both electrically insulating and poorly adhered. In general they will flake off like rust, which is a chemically similar compound, causing a potential for defects in the solar cell. The refractory metals (columns IVB, VB, and VIB in the periodic table) are often used as protective coating. However, molybdenum, which is used as the back electrode in most CIGS solar cells, forms some reactive products during the high temperature phase of the process if used as a back side protective coating. An undesirable aspect of this effect is that the back of the cell becomes covered with a by product that is not sufficiently electrically conductive even though debris formation is generally improved since the iron reaction products may be reduced.

A common method of making a solar module using thin film solar cells deposited on flexible metal foils involves making an electrical contact to the back of the metallic substrate. This becomes more difficult if the back of the foil is rendered poorly conducting by insulating layers formed during the high temperature process. While physical abrasion (e.g., mechanical polishing) can be used to clean off the reaction products, special care must be used so as to not damage the newly formed solar cell in the extra and undesirable manufacturing step. For instance, physical abrasion may induce stresses to the solar cell, which may introduce mechanical defects. In addition, a clean stainless steel surface, which is initially conductive, may over time acquire an oxide surface layer, which will increase the resistance of the interconnect and eventually reduce the power output of the module.

### SUMMARY

Recognized herein is the need for coating(s) with properties which allow a back side of a solar (or photovoltaic) cell to remain intact and electrically conductive after high temperature processing, such as in selenium and/or sulfur environments.

This disclosure provides methods and systems for forming thin film photovoltaic cells on substrates, such as flexible metallic foil substrates. Methods of the disclosure can be used to form high temperature protective coatings for protecting a metallic substrate from reacting with selenium and/or sulfur during forming of an absorber layer of a photovoltaic (or solar) cell.

This disclosure provides a coating for the back side of solar cells deposited on metal foils that remains adherent after a high temperature exposure to selenium, sulfur, or tellurium. This disclosure also provides a coating for the back side of solar cells deposited on metal foils that remains electrically conductive after high temperature exposure to selenium, sulfur, or tellurium. In some cases, a coating material can be applied by magnetron sputtering.

An aspect of the present disclosure provides a photovoltaic (PV) cell, comprising a first layer comprising niobium or tantalum, and a second layer adjacent to the first layer, wherein the second layer comprises an electrically conductive material. The PV cell further comprises a substrate adjacent to the second layer, and an absorber adjacent to the substrate. The absorber can be formed of a photoactive material that is configured to generate electron/hole pairs upon exposure of the absorber to electromagnetic radiation. The absorber can include one or more absorber layers. The PV cell further comprises a transparent window layer adjacent to the absorber layer. In some examples, the first layer can comprise niobium and tantalum. The first layer can include selenium and/or sulfur. In an example, the first layer is substantially free of molybdenum.

Another aspect of the present disclosure provides a method for forming a photovoltaic cell, comprising (a) providing, in a reaction space, a substrate comprising a first layer, wherein the substrate comprises a front side and a back side that is disposed away from the front side, and wherein the first layer comprises copper and indium, and (b) contacting the first layer with a source of selenium or sulfur, thereby converting the first layer to an absorber layer that can be configured to generate electron/hole pairs upon exposure to electromagnetic radiation. A second layer comprising niobium or tantalum is formed adjacent to the back side of the substrate prior to contacting the first layer with the source of selenium or sulfur. A third layer comprising molybdenum or tungsten is formed between the second layer and the substrate.

Another aspect of the present disclosure provides a photovoltaic cell comprising a protective layer that comprises an electrically conductive material, and a substrate adjacent to the protective layer. The PV cell further comprises a barrier layer adjacent to the substrate. The barrier layer can be formed of an electrically conductive material. The PV cell further comprises an absorber (e.g., one or more absorber layers) adjacent to the one or more electrically conductive layers. The absorber can comprise copper and indium. The absorber can be configured to generate electron/hole pairs upon exposure of the absorber to electromagnetic radiation. An optically transparent window layer can be disposed adjacent to the absorber layer. The PV cell can further comprise an electrically non-conductive metal oxide layer adjacent to the window layer, and a transparent metal oxide layer adjacent to the electrically non-conductive metal oxide layer.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention(s) are set forth with particularity in the appended claims. A better understanding of the features and advantages of the present invention(s) will be obtained by reference to the following detailed description that sets forth illustrative embodiments, in which the principles of the invention(s) are utilized, and the accompanying drawings (also “FIG.” and “FIGS.” herein), of which:

FIG. 1 is a schematic cross sectional side view of a photovoltaic cell comprising an absorber formed on a metallic foil substrate, and a back side coating adjacent to the substrate, in accordance with various embodiments of the present disclosure;

FIG. 2 is a schematic cross-sectional side view of a photovoltaic cell comprising an absorber layer deposited on a metallic foil substrate, an adhesion promoting layer adjacent to the substrate, and a back side coating adjacent to the adhesion promoting layer, in accordance with various embodiments of the present disclosure;

FIG. 3 schematically illustrates a photovoltaic cell, in accordance with various embodiments of the present disclosure;

FIG. 4 schematically illustrates a photovoltaic module comprising at least two photovoltaic cells, in accordance with various embodiments of the present disclosure; and

FIG. 5 schematically illustrates a system for forming a photovoltaic cell.

### DETAILED DESCRIPTION

While various embodiments of the invention(s) of the present disclosure have been shown and described herein, it will be obvious to those skilled in the art that such embodiments are provided by way of example only. Numerous variations, changes, and substitutions may occur to those skilled in the art without departing from the invention(s). It should be understood that various alternatives to the embodiments of the invention(s) described herein may be employed in practicing any one of the inventions(s) set forth herein.

The term “photovoltaic cell” or “solar cell,” as used herein, refers to a solid state electrical device having an active material (or absorber) that converts the energy of electromagnetic radiation (or light) into electricity by the photovoltaic (PV) effect.

The term “absorber,” as used herein, generally refers to a photoactive material that, upon exposure to electromagnetic radiation, converts the energy of electromagnetic radiation into electricity by the photovoltaic (PV) effect. An absorber can be configured to generate electricity at select wavelengths of light. An absorber layer can be configured to generate electron and hole pairs. Upon exposure to light, an absorber can generate electron/hole pairs. Examples of absorbers include, without limitation, copper indium gallium di-selenide (CIGS) and copper indium diselenide (CIS).

The term “photovoltaic module” or “solar module,” as used herein, refers to a packaged array of one or more PV cells. The PV module (also “module” herein) can be used as a component of a larger photovoltaic system to generate and supply electricity, such as in commercial and residential applications. A PV module can include a support structure having one or more PV cells. In some embodiments, a PV module includes a plurality of PV cells, which can be interconnected, such as, for example, in series with the aid of interconnects. A PV array can include a plurality of PV modules.

The term “n-type,” as used herein, generally refers to a material that is chemically doped (“doped”) with an n-type dopant. For instance, silicon can be doped n-type using phosphorous or arsenic.

The term “p-type,” as used herein, generally refers to a material that is doped with an p-type dopant. For instance, silicon can be doped p-type using boron or aluminum.

The term “layer,” as used herein, generally refers to a layer of atoms or molecules on a substrate. In some cases, a layer includes an epitaxial layer or a plurality of epitaxial layers. A layer may include a film or thin film. In some situations, a layer is a structural component of a device (e.g., light emitting diode) serving a predetermined device function, such as, for example, an active layer that is configured to generate (or emit) light. A layer generally has a thickness from about one monolayer (ML) to tens of monolayers, hundreds of monolayers, thousands of monolayers, millions of monolayers, billions of monolayers, trillions of monolayers, or more. In an example, a layer is a multilayer structure having a thickness greater than one monolayer. In addition, a layer may include multiple material layers (or sub-layers). In an example, a multiple quantum well active layer includes multiple well and barrier layers. A layer may include a plurality of sub-layers. For example, an active layer may include a barrier sub-layer and a well sub-layer.

The term “substrate,” as used herein, generally refers to any workpiece on which a layer, film or thin film formation is desired. A substrate includes, without limitation, silicon, germanium, silica, sapphire, zinc oxide, carbon (e.g., graphene), SiC, AlN, GaN, spinel, coated silicon, silicon on oxide, silicon carbide on oxide, glass, gallium nitride, indium nitride, titanium dioxide and aluminum nitride, a ceramic material (e.g., alumina, AlN), a metallic material (e.g., stainless steel, tungsten, titanium, copper, aluminum), and combinations (or alloys) thereof.

The term “adjacent” or “adjacent to,” as used herein, includes ‘next to’, ‘adjoining’, ‘in contact with’, and ‘in proximity to’. In some instances, adjacent to components are separated from one another by one or more intervening layers. For example, the one or more intervening layers can have a thickness less than about 10 micrometers (“microns”), 1 micron, 500 nanometers (“nm”), 100 nm, 50 nm, 10 nm, 1 nm, or less. In an example, a first layer is adjacent to a second layer when the first layer is in direct contact with the second layer. In another example, a first layer is adjacent to a second layer when the first layer is separated from the second layer by a third layer.

The term “reaction space,” as used herein, generally refers to any environment suitable for depositing a material layer, film or thin film adjacent to a substrate, or the measurement of the physical characteristics of the material layer, film or thin film. A reaction space can include or be fluidically coupled to a material source. In an example, a reaction space includes a reaction chamber (also “chamber” herein). In another example, a reaction space includes a chamber in a system having a plurality chambers. A reaction space may include a chamber in a system having a plurality of fluidically separated chambers. A system for forming a photovoltaic cell can include multiple reactions spaces. Reactions spaces can be fluidically separated from one another. Some reaction spaces can be suitable for conducting measurements on a substrate or a layer, film or thin film formed adjacent to the substrate.

The present disclosure provides systems and methods for forming photovoltaic cells (also “solar cells” herein). Photovoltaic cells may be electrically connected to one another to form photovoltaic modules, which may be mounted in solar systems. Photovoltaic cells and modules can be adapted to generated electricity upon exposure to electromagnetic radiation (or light).

A copper indium gallium di-selenide (CIGS) photovoltaic cell may be formed by depositing a layer comprising copper, indium and gallium (CIG) adjacent to a front side of the substrate, and contacting the layer with a source of selenium to generate CIGS. The substrate can include a layer of molybdenum at a back side of the substrate. The layer of molybdenum can be used for electrically coupling one photovoltaic cell to another to form a photovoltaic module.

In some cases, it has been recognized that contacting the substrate and the CIG layer with the source of selenium causes the selenium to react with the layer of molybdenum to produce a material that can have reduced electrical conductivity and may not be preferable. The present disclosure provides systems and methods for forming a back contact that remains conductive following exposure to selenium.

Photovoltaic Cells with Protective Layers

An aspect of the present disclosure provides a photovoltaic cell comprising a substrate, at least one barrier layer adjacent to the substrate, and an absorber layer adjacent to the barrier layer. The barrier layer can be formed of an electrically conductive material. The absorber layer can comprise copper indium gallium di-selenide (CIGS) or copper indium diselenide (CIS). The absorber layer is configured to generate electron/hole pairs upon exposure to electromagnetic radiation.

The absorber layer can further include a Group I material, such as a chemical dopant. In some example, the absorber layer further comprises sodium.

The barrier layer can aid in minimizing the migration of material from the substrate into the absorber layer during processing of the photovoltaic cell. Such migration may not be preferred as it may adversely impact the band gap of the absorber layer. For example, in some cases the substrate is a stainless steel substrate comprising chromium and iron, and the barrier layer is configured to provide electrical conductivity between the substrate and the absorber layer and minimize the migration of iron and chromium from the substrate into the absorber layer. The barrier layer can be formed adjacent to a front side of the substrate, which is the side facing incoming electromagnetic radiation during use of the photovoltaic cell.

The barrier layer can be formed of chromium or titanium. In some situations, the photovoltaic cell comprises multiple barrier layers (i.e., barrier stack) between the substrate and the absorber layer. The barrier stack can include alternating material layers, such as alternating chromium and molybdenum layers, alternating niobium and molybdenum layers, alternating titanium and molybdenum layers, or combinations thereof. For example, the photovoltaic cell can include, between the substrate and the absorber layer, a chromium or titanium layer, a molybdenum layer adjacent to the chromium or titanium layer, a chromium or niobium layer adjacent to the molybdenum layer, and a molybdenum layer adjacent to the chromium or niobium layer. In some situations, during formation of the absorber layer adjacent to the barrier stack, selenium from the absorber layer can alloy with the barrier stack, such as, for example, to form a molybdenum and selenium-containing layer (e.g., MoSe₂).

In addition to, or as an alternative, the barrier layer can reflect electromagnetic radiation directed through the absorber layer back into the absorber layer. The barrier layer may be a reflector layer or reflector stack if multiple layers are used to reflect electromagnetic radiation into the absorber layer. In some cases, a barrier layer and reflector layer are provided between the substrate and the absorber layer. In an example, the barrier layer is disposed adjacent to the substrate, and the reflector layer is disposed between the barrier layer and the absorber layer. In another example, the reflector layer is disposed adjacent to the substrate, and the barrier layer is disposed between the reflector layer and the absorber layer.

A protective layer can be provided adjacent to a back side of the photovoltaic cell. The protective layer can comprise an electrically conductive material. The protective layer can be substantially non-reactive to selenium and/or sulfur. Thus, in some situations, upon exposure of the protective layer to a source of selenium or sulfur, selenium or sulfur does not appreciably adsorb onto and/or diffuse into the protective layer. In some cases, the protective layer can comprise one or more of a metal carbide, metal boride, metal silicide or metal nitride. In some examples, the protective layer comprises one or more of titanium, tungsten, molybdenum and zirconium. In some cases, the protective layer comprises one or more of titanium diboride, tungsten carbide, titanium nitride and molybdenum disilicide.

As an alternative, the protective layer can comprise a material that, upon reaction with selenium or sulfur, forms a material with electrical conductivity that is suitable to provide an electrical flow path to the substrate. In some cases, the material is selected such that, upon reaction of the material with selenium or sulfur, the material does not become electrically insulating or semiconducting. In some examples, the protective layer comprises niobium. The reaction of niobium with selenium or sulfur provides a material that can have an electrical conductivity that can be suitable for use as a back electrode of the photovoltaic cell. In an example, the protective layer reacts with selenium to form niobium selenide, such as, e.g., NbSe_{y}, wherein ‘y’ is a number greater than zero. In other examples, the protective layer comprises tantalum. The protective layer in such a case can react with tantalum to form, for example, TaSe_{y}, wherein ‘y’ is a number greater than zero. In some cases, such as at lower temperature, niobium may not appreciably react with selenium or sulfur. In such a case, the protective layer comprising niobium may be substantially free of selenium or sulfur.

The protective layer, in some cases, is free of molybdenum. In some examples, the protective layer has a molybdenum content that is less than about 20%, 15%, 10%, 5%, 4%, 3%, 2%, 1%, 0.1%, 0.01%, 0.001%, 0.0001%, 0.00001%, or less. In some cases, the protective layer is free of tungsten. In some examples, the protective layer has a tungsten content that is less than about 20%, 15%, 10%, 5%, 4%, 3%, 2%, 1%, 0.1%, 0.01%, 0.001%, 0.0001%, 0.00001%, or less. The molybdenum or tungsten content can be estimated by measuring the number of molybdenum or tungsten atoms in a given area or volume of the protective, and dividing the number of molybdenum or tungsten atoms by the total number of atoms in the given area or volume of the protective layer. This may be accomplished with the aid of various spectroscopic techniques, such as, for example, x-ray photoelectron spectroscopy (XPS).

In some situations, the protective layer comprises niobium and selenium and/or sulfur. The protective layer can comprise selenium and/or sulfur at an outer portion of the protective layer. In some examples, the protective layer has a selenium and/or sulfur content of at least about 0.01 monolayers (ML), 0.1 ML, 0.2 ML, 0.3 ML, 0.4 ML, 0.5 ML, 0.6 ML, 0.7 ML, 0.8 ML, 0.9 ML, 1.0 ML, 2 ML, 3 ML, 4 ML, 5 ML, 10 ML, 100 ML, or 1000 ML. The selenium and/or sulfur content may be measured with XPS. In some situations, the protective layer has a thickness from about 10 nanometers (nm) to 500 nm.

In some situations, the protective layer comprises niobium and is free of molybdenum, tungsten, or both molybdenum and tungsten. The protective layer comprising niobium can have a molybdenum and/or tungsten content that is less than 20%, 15%, 10%, 5%, 4%, 3%, 2%, 1%, 0.1%, 0.01%, 0.001%, 0.0001%, 0.00001%, or less. In some examples, the protective layer comprises niobium and is substantially free of molybdenum, tungsten, or both molybdenum and tungsten.

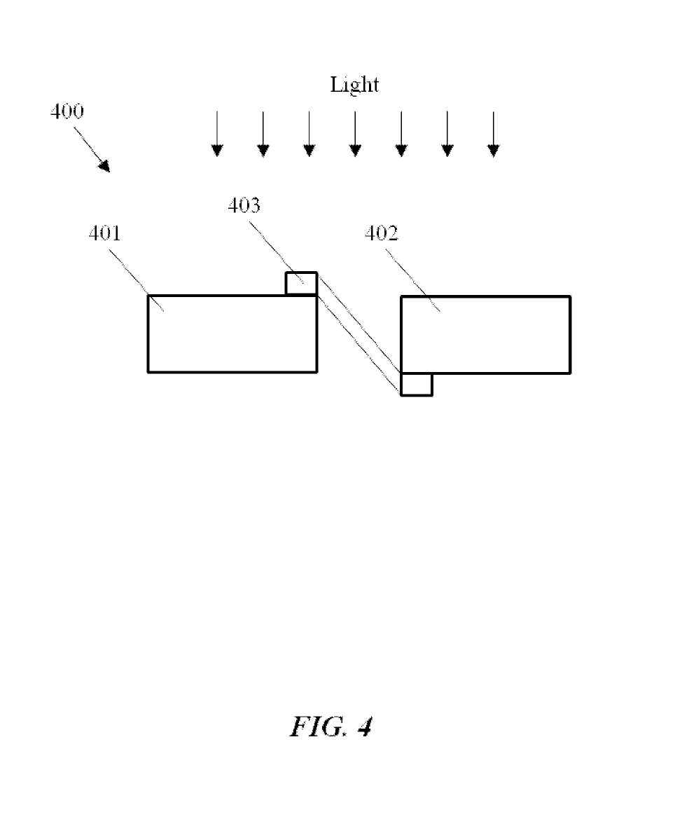

The protective layer may be used to electrically couple one photovoltaic cell to another photovoltaic cell (see, e.g., FIG. 4). The protective layer can enable the formation of an electrical contact between a back side of one photovoltaic cell and a front side of an adjacent photovoltaic cell, thereby providing a photovoltaic module.

The protective layer can have an electrical conductivity that is suited for use as a back electrode of a photovoltaic cell. The protective layer can have a high electrically conductivity (or low electrical resistivity). In some examples, the protective layer has an electrical resistivity from about 0.1 mΩ cm to 0.6 mΩ cm at 25° C. A naiobium and selenium (e.g., NbSe) layer, for example, can have an electrical resistivity of about 0.35 mΩcm at 25° C. As another example, a tantalum and selenium (e.g., TaSe2) layer has an electrical resistivity of about 0.40 mΩcm at 25° C.

The photovoltaic cell can further comprise an adhesion-promoting (also “adhesion” herein) layer between the protective layer and the substrate. The adhesion-promoting layer can be configured to promote adhesion between the protective layer and the substrate. In some examples, the adhesion-promoting layer comprises one or more of chromium, titanium and molybdenum.

The photovoltaic cell can further include an optically transparent window layer adjacent to the absorber layer. The window layer can be doped with an n-type chemical dopant. The absorber layer and window layer can be oppositely doped n-type and p-type. In an example, the absorber layer is p-type and the window layer is n-type, and the absorber layer and window layer form a p-n junction. The window layer can include cadmium or zinc. In an example, the window layer is formed of cadmium and sulfur. In another example, the window layer is formed of zinc sulfide. The window layer can be optically transparent to electromagnetic radiation.

The photovoltaic cell can further include an electrically non-conductive oxide layer adjacent to the window layer, and a transparent oxide layer adjacent to the electrically non-conductive oxide layer. The electrically non-conductive oxide layer can include an electrically non-conductive metal oxide. The electrically non-conductive oxide layer can be transparent. The transparent oxide layer can be a metal oxide layer. In an example, the electrically non-conductive oxide layer is formed of aluminum zinc oxide (AZO). In some examples, the electrically non-conductive oxide layer can have a resistivity from about 1Ω cm to 4Ω cm. In an example, the transparent oxide layer can include indium tin oxide (ITO). The transparent oxide layer can aid in providing electrical connectivity to the absorber. The transparent oxide layer can be electrically conductive. In some examples, the transparent metal oxide layer can have a resistivity less than about 1Ω cm, 0.1Ω cm, 0.01Ω cm, or 0.001Ω cm.

As an alternative to the electrically non-conductive oxide layer, any material that is electrically non-conductive and transparent can be used. As an alternative to the transparent oxide layer, any material that is electrically conductive and transparent can be used.

The photovoltaic cell can include a first electrode in electrical contact with the back side of the substrate and a second electrode in electrical contact with the absorber layer through a layer disposed adjacent to the absorber layer, such as, for example, the transparent oxide layer. In an example, the first electrode is in contact with the protective layer and the second electrode is in contact with the transparent oxide layer.

The substrate can include stainless steel, aluminum or titanium. In some examples, the substrate comprises stainless steel, which can include chromium and iron. The substrate can be an electrically conductive substrate, such as, for example, a metallic foil substrate.

Reference will now be made to the figures. It will be appreciated that the figures (and features therein) are not necessarily drawn to scale.

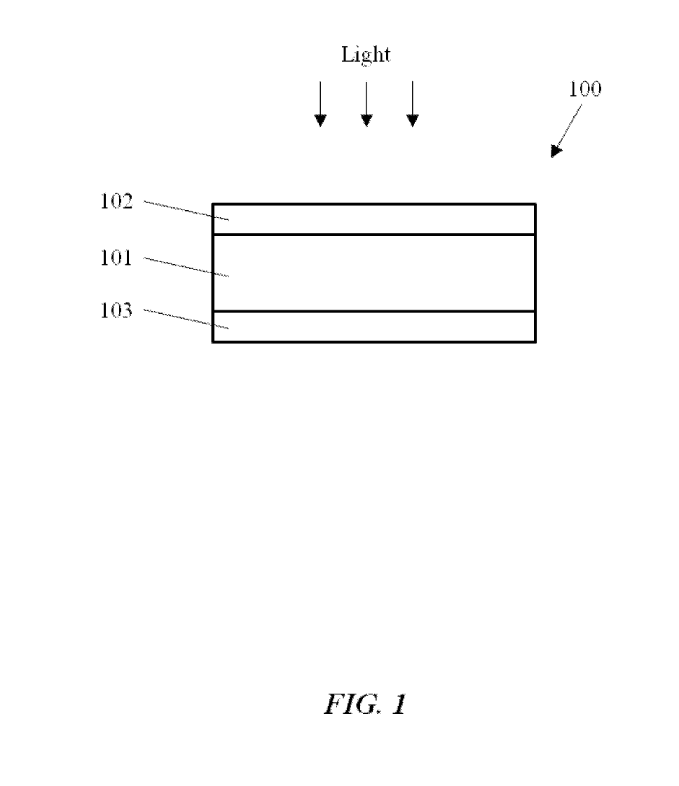

FIG. 1 schematically illustrates a thin film solar cell 100 comprising a metallic foil substrate 101, an absorber layer 102, and a protective back side coating layer 103. The direction of incoming light during operation of the solar cell 100 is indicated by arrows. The substrate 101 can be a 400 series stainless steel with a thickness from about 0.0001 to 0.01 inches, or 0.001 to 0.006 inches. Aluminum, titanium or other metallic foils can be used instead of stainless steel. The absorber layer 102 can include a plurality of layers of a photovoltaic material, such as, for example, alternating layers of copper, indium, gallium and selenium. In some examples, a CIGS or CIS absorber layer can include 5 to 6 individual layers (or sub-layers) with a total thickness from about 0.5 micrometers (microns) to 5 microns. The protective back side coating layer 103 can be selected to be a material that resists reaction with selenium and sulfur vapors at high temperatures and remains electrically conductive. The protective layer 103 can have a thickness from about 10 nanometers (nm) to 100 microns, 50 nm to 10 microns, or 100 nm to 1 micron.

The protective layer 103 can be formed of a refractory metal. The protective layer 103 can be formed of an electrically conducive material. In some examples, the protective layer 103 is formed of a boride, carbide, nitride or silicide. The protective layer 103 can be formed of a material that has a melting point higher than that of the material of the absorber layer 102.

The absorber layer 102 and protective layer 103 may be formed by vapor phase deposition techniques. In some examples, the absorber layer 102 and protective layer 103 are formed by physical vapor deposition, such as magnetron sputtering. In some examples, titanium diboride or tungsten carbide is provided in plate form as a magnetron sputtering target and used to deposit the protective layer 103.

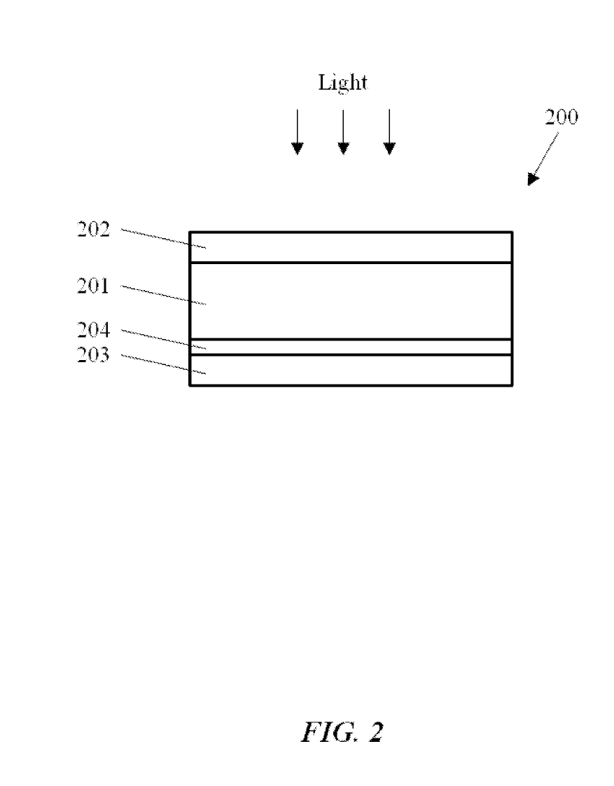

FIG. 2 shows a photovoltaic cell 200 comprising a substrate 201, absorber layer 202, protective layer 203 and an adhesion-promoting layer 204. The adhesion-promoting layer can aid in improving the adhesion of the protective layer 203 to the substrate 201. The adhesion-promoting layer can be formed of a refractive metal, such as, for example, one or more metals selected from chromium, titanium and nickel. The adhesion-promoting layer 204 can be thinner than the protective layer 203.

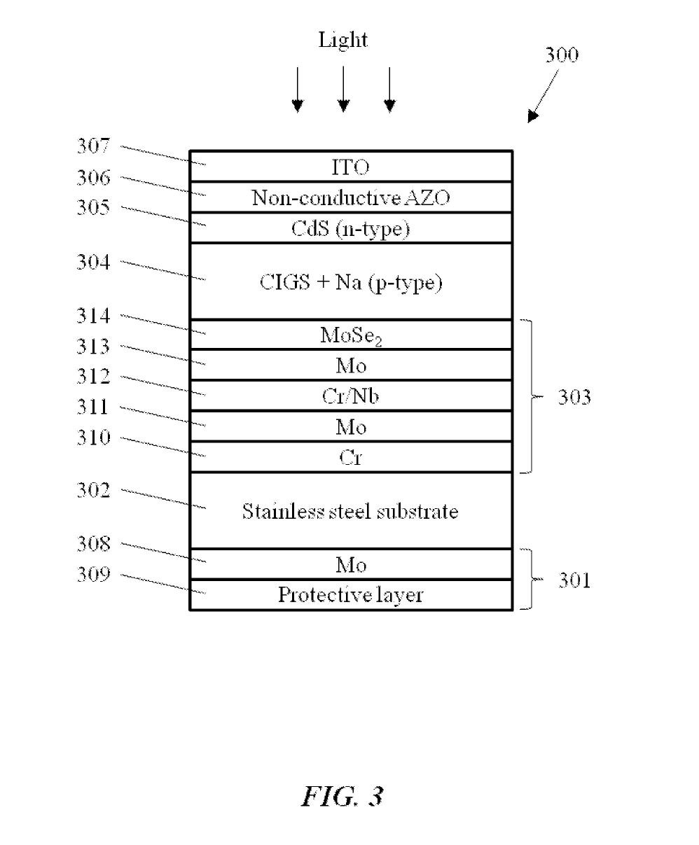

FIG. 3 shows a photovoltaic cell 300 comprising a back electrode 301, a substrate 302, a barrier stack 303, an absorber 304, a window layer 305, a non-conductive layer 306 and an electrically conductive oxide layer 307. The back electrode 301 can include a layer of an electrically conductive material 308, such as molybdenum, titanium or tungsten, and a protective layer 309 adjacent to the layer 308. The protective layer 309 can be as described above and elsewhere herein.

The absorber 304 can include at least 1, 2, 3, 4, 5, 6, 7, 8, 9, 10, 20, 30, 40, 50, 100, or 1000 layers. The absorber can be a CIS or CIGS absorber. In some examples, the absorber 304 includes a CIGS absorber with 1, 2, 3, 4, 5, 6, 7, 8, 9, or 10 individual CIGS layers. The absorber 304 (e.g., silicon absorber) can include a dopant, such as an n-type or p-type dopant. In an example, the absorber (e.g., silicon absorber) is doped p-type. In addition, the absorber 304 can include an alkali metal, such as lithium, sodium, potassium, rubidium, or combinations thereof.

The window layer 305 can comprise cadmium or zinc. The window layer 305 can be optically transparent (or at least partially transparent) to enable incoming electromagnetic radiation to come in contact with the absorber 304. In an example, the window layer 305 comprises cadmium sulfide. In another example, the window layer 305 comprises zinc sulfide.

The barrier stack 303 can include a first barrier layer 310, second barrier layer 311, third barrier layer 312, fourth barrier layer 313, and fifth barrier layer 314. In some cases, the barrier stack 303 can include more or fewer layers. The barrier stack 303 can include at least 1, 2, 3, 4, 5, 6, 7, 8, 9, 10, 20, 30, 40, 50, 100, or 1000 layers. The barrier stack 303 can be configured to reflect electromagnetic radiation into the absorber 304.

In some examples, the first barrier layer 310 comprises chromium, the second barrier layer 311 comprises molybdenum, the third barrier layer 312 comprises chromium and/or niobium, the fourth barrier layer 313 comprises molybdenum, and the fifth barrier layer 314 comprises molybdenum. The fifth barrier layer 314 can alloy with selenium or sulfur from the absorber 304 to form a molybdenum selenide (e.g., MoSe₂) or a molybdenum sulfide (e.g., MoS₂) layer. Such alloying can occur during processing, including high temperature treatment of the photovoltaic cell 300.

The substrate 302 can be a stainless steel substrate, such as a thin foil stainless steel substrate. As an alternative, the substrate 302 can be an aluminum substrate.

The layer 306 can comprise an electrically non-conductive material, such as aluminum zinc oxide (AZO), intrinsic zinc oxide (e.g., oxygen-rich or stoichiometric zinc oxide), or tin oxide. The layer 307 can include an electrically conductive oxide, such as indium tin oxide or oxygen deficient AZO.

A photovoltaic module can include at least 1, 2, 3, 4, 5, 6, 7, 8, 9, 10, 20, 30, 40, 50, 100, or 1000 photovoltaic cells. In some cases, photovoltaic cells can be electrically coupled to one another in series to form a photovoltaic module. As an alternative or in addition to, at least some photovoltaic cells can be electrically coupled to one another in parallel.

FIG. 4 shows a photovoltaic module 400 comprising a first photovoltaic cell 401 and a second photovoltaic cell 402. The first photovoltaic cell 401 and second photovoltaic cell 402 can be as described above and elsewhere herein, such as the photovoltaic cell 300 of FIG. 3. A front side of the first photovoltaic cell 401 is electrically connected to a back side of the second photovoltaic cell 402 with the aid of an electrical coupling member 403. Although two photovoltaic cells are illustrated, the photovoltaic module 400 can include any number of photovoltaic cells. Methods and systems for interconnecting photovoltaic cells are described in Patent Cooperation Treaty (PCT) Patent Application No. PCT/US2011/38887 and PCT/US2012/068302, each of which is entirely incorporated herein by reference. Photovoltaic modules of the present disclosure may include features of modules described in PCT/US2012/020829, which is entirely incorporated herein by reference.

### Methods for Forming Photovoltaic Cells

Another aspect of the present disclosure provides methods for forming photovoltaic cells. Such methods can be used to form any photovoltaic cell of the disclosure.

A method for forming a photovoltaic cell comprises providing a substrate in a reaction space. The substrate can be a stainless steel or aluminum substrate that is directed into the reaction space with the aid of a roll-to-roll system (see below). The substrate comprises a front side and a back side, and the back side is disposed away from the front side. Next, a first layer is formed adjacent to the front side of the substrate. The first layer can comprise copper and indium. In some cases, the first layer further comprises gallium. The first layer can be formed by exposing the substrate or one or more layers adjacent to the substrate (e.g., barrier stack) to a vapor source of copper, indium and, in some cases, gallium. In some examples, the vapor sources are provided with the aid of one or more magnetron sputtering systems. For example, a magnetron sputtering system comprising a copper target may be used to provide the source of copper, a magnetron sputtering system comprising an indium target may be used to provide the source of indium, and, in some cases, a magnetron sputtering system comprising a gallium target may be used to provide the source of gallium. Magnetron sputtering systems that may be used with methods of the disclosure are described in PCT/US2011/30793 and PCT/US2012/050418, each of which is entirely incorporated herein by reference.

Next, the first layer is contacted with a source of selenium or sulfur to convert the first layer to an absorber layer (e.g., CIGS, CIS). The first layer can be contacted with the source of selenium or sulfur either in the same reaction space or a different reaction space. In some situations, the substrate is also contacted with the source of selenium or sulfur. A source of selenium can be provided from a gaseous source (e.g., H₂Se or diethyl selenide), for example. As another example, the source of selenium can be provided from an evaporative source (e.g., selenium pellets). Sulfur can be provided with the aid of a gas phase sulfur source, such as H₂S. Upon contacting the first layer with sulfur or selenium, the substrate and the first layer can be heated to a temperature from about 400° C. to 600° C.

The absorber layer can be doped n-type or p-type. Some absorbers are n-type or p-type without any additional doping. For example, CIGS, as formed, can be p-type and may not require any additional p-type doping. In some cases, upon formation of the absorber layer (e.g., silicon absorber layer), a precursor of an n-type or p-type dopant is introduced for incorporating the n-type or p-type dopant into the absorber layer. As an alternative, following formation of the absorber layer, the n-type or p-type dopant can be introduced into the absorber layer by ion implantation followed by annealing. In some situations (e.g., CIGS), a sodium precursor is provided to the absorber layer to include sodium in the absorber layer.

During formation of the photovoltaic cell, a second layer can be formed adjacent to the back side of the substrate. The second layer can be a protective layer, as described above and elsewhere herein. The second layer can be formed before contacting the substrate and the first layer with the source of selenium or sulfur. In some cases, the second layer is formed before forming the first layer adjacent to the substrate. In some cases, the second layer is substantially free of molybdenum and tungsten.

In some examples, the second layer has a molybdenum content that is less than about 20%, 15%, 10%, 5%, 4%, 3%, 2%, 1%, 0.1%, 0.01%, 0.001%, 0.0001%, 0.00001%, or less. The molybdenum content can be estimated by measuring the number of molybdenum atoms in a given area or volume, and dividing the number of molybdenum atoms by the total number of atoms in the given area or volume of the second layer. This may be accomplished with the aid of various spectroscopic techniques, such as, for example, x-ray photoelectron spectroscopy (XPS).

In some examples, the second layer has a tungsten content that is less than about 20%, 15%, 10%, 5%, 4%, 3%, 2%, 1%, 0.1%, 0.01%, 0.001%, 0.0001%, 0.00001%, or less. The tungsten content can be estimated by measuring the number of tungsten atoms in a given area or volume, and dividing the number of tungsten atoms by the total number of atoms in the given area or volume of the second layer.

In some cases, the second layer comprises a metal carbide, metal nitride, metal boride, or metal silicide. As an alternative, the second layer comprises niobium (Nb). The second layer can be formed by a vapor phase deposition technique, such as physical vapor deposition. For example, a magnetron sputtering apparatus can provide a vapor phase material (e.g., Nb) of the second layer. In cases in which niobium is desired or otherwise used, the magnetron sputtering apparatus can include a niobium target. If a metal carbide, boride, nitride or silicide is desired, the magnetron sputtering apparatus can include a target of the metal (e.g., tungsten or titanium), and gas phase precursors can be used to provide carbon (e.g., CH₄), boron (e.g., Br₂), nitrogen (e.g., N₂, NH₃) or silicon (e.g., Si₂H₆).

In some cases, the absorber layer comprises CIGS, and during processing the first layer is contacted with the source of selenium. As an alternative, the absorber layer comprises CIS, and during processing the first layer is contacted with the source of selenium.

Upon formation of the absorber layer, a window layer can be formed adjacent to the absorber. The window layer in some cases comprises cadmium and sulfur. As an alternative, the window layer comprises zinc and sulfur. The window layer can be n-type. The window layer can be formed by exposing the absorber layer to a source of cadmium or zinc, for example. For instance, a magnetron sputtering system comprising a cadmium (or zinc) target can be used to provide cadmium. A sulfur precursor (e.g., H₂S) can be provided as a source of sulfur for the cadmium sulfur (or zinc sulfur) layer. As an alternative, a cadmium sulfide or zinc sulfide target may be used in a magnetron sputtering apparatus to generate the window layer. In some situations, the window layer comprises cadmium sulfide, and the window layer is formed by contacting the absorber layer with the source of cadmium and a source of sulfur (e.g., H₂S).

In some cases, upon formation of the window layer, a layer of an electrically non-conductive material is formed adjacent to the window layer. In some examples, the electrically non-conductive material is zinc oxide. In an example, the electrically non-conductive material is aluminum zinc oxide (AZO). The electrically non-conductive material can be deposited with the aid of a physical vapor deposition technique, such as sputtering. In an example, to form a zinc oxide, a zinc target can be used to provide a source of zinc to deposit zinc on the window layer, and a source of oxygen (e.g., O₂) can be brought in contact with the deposited zinc to form a zinc oxide. In some situations, a source of aluminum (e.g., AlH₃) can be provided to form AZO.

The layer of the electrically non-conductive material can be at least partially transparent to electromagnetic radiation. In some cases, the layer of the electrically non-conductive material can be transparent to select wavelengths of electromagnetic radiation.

A transparent oxide layer can be formed adjacent to layer of the electrically non-conductive material. In some situations, the transparent oxide layer is indium tin oxide, which may be formed using, for example, a magnetron sputtering apparatus with an indium target and a tin target can be used to deposit a layer of indium and tin on the layer of the electrically non-conductive material. A source of oxygen (e.g., O₂) can be provided to deposit oxygen into the layer of indium and tin.

In some cases, a barrier layer or barrier stack comprising a plurality of layers is formed between the substrate and the absorber layer. A barrier layer can be formed by exposing the nascent photovoltaic cell to a source of barrier layer material, such as, for example, a source of molybdenum, For instance, a barrier layer can be formed of a material comprising molybdenum, chromium, niobium, tungsten, or titanium, and the material can be introduced using a source of the material, such as magnetron sputtering apparatus with a target comprising the source. In some cases, a sputtering system comprises multiple magnetron sputtering apparatuses, each with a given target for a particular barrier layer material. The sputtering system can be used to form an individual barrier layer, or sequentially form a barrier stack comprising multiple barrier layers.

In an example, a barrier stack is formed by contacting the substrate with a source of chromium or titanium to form a layer comprising chromium or titanium. Next, a molybdenum layer is formed adjacent to the layer of chromium or titanium, a chromium or niobium layer is formed adjacent to the molybdenum layer, and a molybdenum layer is formed adjacent to the chromium or niobium layer.

Device layers may be formed with the aid of various deposition techniques. In some embodiments, device layers are formed with the aid of chemical vapor deposition (CVD), atomic layer deposition (ALD), plasma enhanced CVD (PECVD), plasma enhanced ALD (PEALD), metal organic CVD (MOCVD), hot wire CVD (HWCVD), initiated CVD (iCVD), modified CVD (MCVD), vapor axial deposition (VAD), outside vapor deposition (OVD) and physical vapor deposition (e.g., sputter deposition, evaporative deposition).

### Systems for Forming Photovoltaic Cells

Another aspect of the disclosure provides a system for forming a photovoltaic cell. The system can include a deposition system, a pumping system in fluid communication with the deposition system, and a computer system (or controller) having a computer processor (also “processor” herein) for executing machine readable code implementing a method for forming the photovoltaic cell. The code may implement any of the methods provided herein. The pumping system can be configured to purge or evacuate the deposition system.

The deposition system can include one or more reaction spaces for forming material layers of the photovoltaic cell. In some situations, the deposition system is a roll-to-roll deposition system with one or more interconnected reaction chambers, which can be fluidically isolated from one another (e.g., with the aid of purging or pumping at locations in-between the chambers).

The pumping system can include one or more vacuum pumps, such as one or more of a turbomolecular (“turbo”) pump, a diffusion pump and a mechanical pump. A pump may include one or more backing pumps. For example, a turbo pump may be backed by a mechanical pump.

In some embodiments, the controller is configured to regulate one or more processing parameters, such as the substrate temperature, precursor flow rates, growth rate, carrier gas flow rate and deposition chamber pressure. The controller, in some cases, is in communication with valves between the storage vessels and the deposition chamber, which aids in terminating (or regulating) the flow of a precursor to the deposition chamber. The controller includes a processor configured to aid in executing machine-executable code that is configured to implement the methods provided herein. The machine-executable code is stored on a physical storage medium, such as flash memory, a hard disk, or other physical storage medium configured to store computer-executable code.

In some embodiments, the controller is configured to regulate one or more processing parameters. In some situations, the controller regulates the growth temperature, carrier gas flow rate, precursor flow rate, growth rate and/or growth pressure.

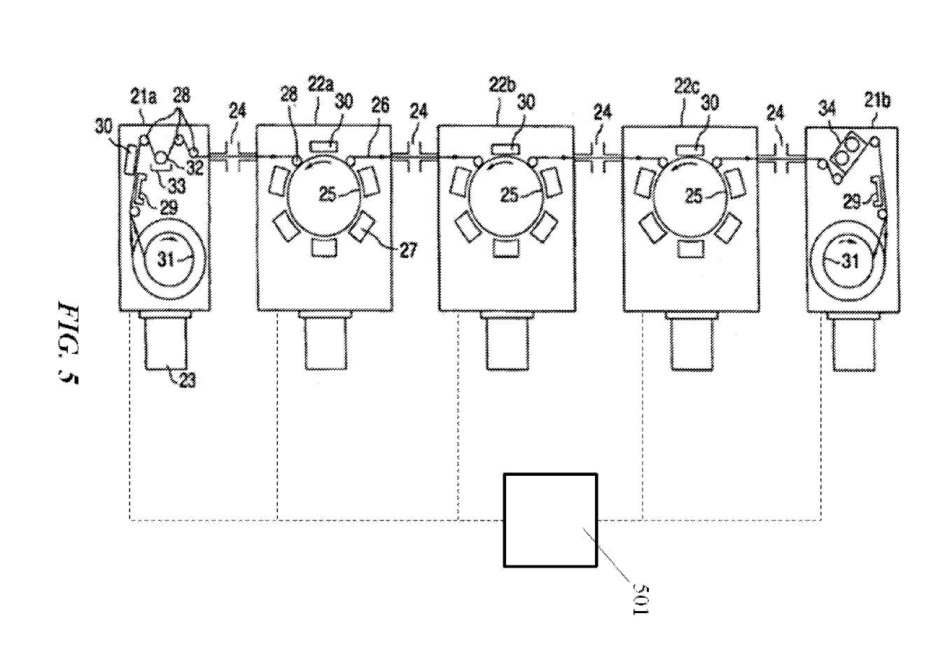

FIG. 5 shows a system for forming a photovoltaic cell. The system comprises a series of connected series of roll (i.e., web) coating sputtering machines employing drums 25 with arrays of magnetron sputtering devices 27. FIG. 5 depicts various operations that can be accomplished on the web in free span regions between idle or drive rollers. For instance, surface etching or plasma treatment 29, planar magnetron deposition 30, and dual rotary magnetron deposition 34. Any of the operations can be performed on either side of the substrate. In practice, it may be convenient to use magnetron sputtering to coat the protective layer and any adhesion layer onto the back side of the substrate as suggested by 34. By utilizing the free span regions between idle rollers, the web can be coated all the way to its edge. This may be more difficult on the drum because there may be at least a small amount of coating that may deposit on the drum, and the build up over time may compromise the thermal contact of the web to the drum. The system of FIG. 5 may have features and functionalities as described in U.S. Pat. No. 6,974,976, which is entirely incorporated herein by reference.

With reference to FIG. 5, in some examples, in the direction perpendicular to the view plane the system (or machine) is sized to support substrates between about two and four feet wide. This width may not be a fundamental equipment limit; rather, it may recognize the practical difficulty of obtaining quality substrate material in wider rolls. The machine is equipped with an input, or load, module 21a and a symmetrical output, or unload, module 21b. Between the input and output modules are process modules 22a, 22b, and 22c. The number of process modules may be varied to match the requirements of the coating that is being produced. Each module has a means of pumping to provide the required vacuum and to handle the flow of process gases during the coating operation. The vacuum pumps are indicated schematically by elements 23 on the bottom of each module. A real module may have a number of pumps placed at other locations selected to provide optimum pumping of process gases. High throughput turbomolecular pumps are preferred for this application. The modules are connected together at slit valves 24, which contain very narrow low conductance isolation slots to prevent process gases from mixing between modules. These slots may be separately pumped if required to increase the isolation even further. Alternatively, a single large chamber may be internally segregated to effectively provide the module regions, but it then becomes much harder to add a module at a later time if process evolution requires it.

Each process module can be equipped with a rotating coating drum 25 on which web substrate 26 is supported. Arrayed around each coating drum is a set of dual cylindrical rotary magnetron housings 27. Conventional planar magnetrons can be substituted for the dual cylindrical rotary magnetrons; however, efficiency can be reduced and the process may not be as stable over long run times. The coating drum may be sized larger or smaller to accommodate a different number of magnetrons than the five illustrated in the drawing. Web substrate 26 is managed throughout the machine by rollers 28. More guide rollers may be used in a real machine. Those shown here are the minimum needed to present a coherent explanation of the process. In an actual machine some rollers are bowed to spread the web, some move to provide web steering, some provide web tension feedback to servo controllers, and others are mere idlers to run the web in desired positions. The input/output spools and the coating drums are actively driven and controlled by feedback signals to keep the web in constant tension throughout the machine. In addition, the input and output modules each contain a web splicing region 29 where the web can be cut and spliced to a leader or trailer section to facilitate loading and unloading of the roll. Heater arrays 30 are placed in locations where necessary to provide web heating depending upon process requirements. These heaters are a matrix of high temperature quartz lamps laid out across the width of the coating drum (and web). Infrared sensors provide a feedback signal to servo the lamp power and provide uniform heating across the drum. In addition coating drums 25 are equipped with an internal controllable flow of water or other fluid to provide web temperature regulation.

The input module accommodates the web substrate on a large spool 31, which is appropriate for metal foils (e.g., stainless steel, copper, etc.) to prevent the material from taking a set during storage. The output module contains a similar spool to take up the web. The pre-cleaned substrate web first passes by heater array 30 in module 21a, which provides at least enough heat to remove surface adsorbed water. Subsequently, the web can pass over roller 32, which can be a special roller configured as a cylindrical rotary magnetron. This allows the surface of electrically conducting (metallic) webs to be continuously cleaned by direct current (DC), alternating current (AC), or radiofrequency (RF) sputtering as it passes around the roller/magnetron. The sputtered web material is caught on shield 33, which is periodically changed. Another roller/magnetron may be added (not shown) to clean the back surface of the web if required. Direct sputter cleaning of a conductive web will cause the same electrical bias to be present on the web throughout the machine, which, depending on the particular process involved, might be undesirable in other sections of the machine. The biasing can be avoided by sputter cleaning with linear ion guns instead of magnetrons, or the cleaning may be accomplished in a separate smaller machine prior to loading into the large roll coater. Also, a corona glow discharge treatment can be performed at this position without introducing an electrical bias. If the web is polyimide material electrical biases are not passed downstream through the system. However, polyimide contains excessive amounts of water. For adhesion purposes and to limit the water desorption, a thin layer of metal (typically chromium or titanium) is routinely added. This makes the surface conductive with similar issues encountered with the metallic foil substrates.

Next, the web passes into the first process module 22a through valve 24 and the low conductance isolation slots. The coating drum is maintained at an appropriate process temperature by heater array 30. Following the direction of drum rotation (arrow) the full stack of barrier layers (or reflection layers) begins with the first two magnetrons depositing chromium and molybdenum layers one after the other. The next magnetron provides a thin chromium or niobium layer, followed by a thin molybdenum layer.

Next, the web passes into the next process module, 22b, for deposition of the p-type graded CIGS layer. Heater array 30 maintains the drum and web at the required process temperature. The first magnetron deposits a layer of copper indium diselenide while the next three magnetrons put down layers with increasing amounts of gallium (or aluminum), thus increasing and grading the band gap. The grading may be inverted by rearrangement of the same set of magnetrons. The last magnetron in the module deposits a thin layer of a window layer, such as, for example, n-type ZnS (or ZnSe), by RF sputtering from a planar magnetron, or a sacrificial metallic layer, which becomes part of the top n-type layer and defines the p-n junction.

In some cases, prior to the web passing into the process module 22b, a protective layer is deposited on a back side of the substrate. The protective layer, in some examples, comprises niobium, and in some cases can be substantially free of molybdenum, tungsten, or both. The protective layer can be deposited prior to depositing the barrier layer adjacent to the substrate. The protective layer can be formed, for example, by providing a dual cylindrical rotary magnetron 34 in the module 21a and coating the backside of the substrate with niobium prior to formation of the barrier layer(s) in the module 22a.

Following the module 22b, the web is transferred into the final process module, 22c, where again heater array 30 maintains the appropriate process temperature. The first magnetron deposits a thin layer of aluminum doped ZnO (AZO) which has a higher resistance to form and maintain the p-n junction in coordination with the previous layer. The remaining four magnetrons deposit a relatively thick, highly conductive and transparent aluminum doped ZnO layer that completes the top electrode. Extra magnetron stations (not shown) can be added for sputtering grid lines using an endless belt mask rotating around the magnetrons. If an AR layer is to be placed on top of the cell, the machine can have an additional process module(s) in which the appropriate layer or layer stack can be deposited. The extra modules can also be equipped with moving, roll compatible, masking templates to provide a metallic grid and bus bar for making electrical contact to the top electrode. The extra modules and masking equipment adds significantly to the cost of producing the cell, and may only be justified for high value added applications like space power systems.

Next, the web passes into output module 21b, where it is wound onto the take up spool. However, an additional operation can be performed here, which is beneficial in the later processing of the cells into modules. A dual cylindrical rotary magnetron 34 can be used to pre-wet the back of the substrate foil with solder. Metallic tin may have preferable properties of the available solder materials for use with a stainless steel foil, but there are many solder formulations that will work. Pre-wetting may be unnecessary for a copper foil if it is kept clean. An ion gun sputter pre-cleaning of the back surface of the foil before the solder sputtering may also be done in the output module similar to that in the input module. In addition the web temperature may be below the melting point of the pre-wetting solder (about 232° C. for tin).

The system of FIG. 5 further comprises a controller 501 (or control system) that is programmed or otherwise configured to regulate one or more processing parameters of the system, such as substrate temperature, precursor flow rates, magnetron sputtering operation (e.g., magnetron power), RF power, heater power, growth rate, carrier gas flow rate and module pressure. The controller 501 can be in communication (dashed lines) with various components of the system, including, without limitation, the modules, valves between the modules, precursor valves, the pumping system of the system (not shown), and a motor or actuator regulating the rotation of the spools 31. The controller includes a processor configured to aid in executing machine-executable code that is configured to implement the methods provided above and elsewhere herein. The machine-executable code is stored on a physical storage medium (not shown), such as flash memory, a hard disk, or other physical storage medium configured to store computer-executable code.

Aspects of the systems and methods provided herein can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

Devices, systems and methods provided herein may be combined with or modified by other devices, systems and methods, such as devices, systems and/or methods described in U.S. Pat. No. 8,207,012 to Pinarbasi et al., U.S. Patent Publication No. 2010/0140078 to Pinarbasi et al. and U.S. Patent Publication No. 2012/0006398 to Nguyen et al., each of which is entirely incorporated herein by reference.

Unless the context clearly requires otherwise, throughout the description and the claims, words using the singular or plural number also include the plural or singular number respectively. Additionally, the words ‘herein,’ ‘hereunder,’ ‘above,’ ‘below,’ and words of similar import refer to this application as a whole and not to any particular portions of this application. When the word ‘or’ is used in reference to a list of two or more items, that word covers all of the following interpretations of the word: any of the items in the list, all of the items in the list and any combination of the items in the list.

It should be understood from the foregoing that, while particular implementations have been illustrated and described, various modifications may be made thereto and are contemplated herein. An embodiment of one aspect of the disclosure may be combined with or modified by an embodiment of another aspect of the disclosure. It is not intended that the invention(s) be limited by the specific examples provided within the specification. While the invention(s) has (or have) been described with reference to the aforementioned specification, the descriptions and illustrations of embodiments of the invention(s) herein are not meant to be construed in a limiting sense. Furthermore, it shall be understood that all aspects of the invention(s) are not limited to the specific depictions, configurations or relative proportions set forth herein which depend upon a variety of conditions and variables. Various modifications in form and detail of the embodiments of the invention(s) will be apparent to a person skilled in the art. It is therefore contemplated that the invention(s) shall also cover any such modifications, variations and equivalents.

What is claimed is:

1. A photovoltaic cell, comprising:
a first layer comprising niobium or tantalum;
a second layer adjacent to said first layer, wherein said second layer comprises an electrically conductive material;
a substrate adjacent to said second layer;
an absorber adjacent to said substrate, wherein said absorber comprises a photoactive material that generates electron/hole pairs upon exposure to electromagnetic radiation; and
a transparent window layer adjacent to said absorber.

2. The photovoltaic cell of claim 1, further comprising an electrically non-conductive metal oxide layer adjacent to said window layer.

3. The photovoltaic cell of claim 2, further comprising a transparent metal oxide layer adjacent to said electrically non-conductive metal oxide layer.

4. The photovoltaic cell of claim 1, wherein said window layer comprises cadmium and sulfur.

5. The photovoltaic cell of claim 1, wherein said window layer is n-type.

6. The photovoltaic cell of claim 1, wherein said absorber comprises copper indium gallium di-selenide.

7. The photovoltaic cell of claim 6, wherein said CIGS is p-type.

8. The photovoltaic cell of claim 1, wherein said absorber further comprises sodium.

9. The photovoltaic cell of claim 1, wherein said substrate comprises stainless steel or aluminum.

10. The photovoltaic cell of claim 1, further comprising a barrier layer between said substrate and said absorber, wherein said barrier layer is formed of an electrically conductive material.

11. The photovoltaic cell of claim 10, wherein said barrier layer comprises chromium or titanium.

12. The photovoltaic cell of claim 11, further comprising, between said barrier layer and said absorber, a molybdenum layer adjacent to said barrier layer, a chromium or niobium layer adjacent to said molybdenum layer, and a molybdenum layer adjacent to said chromium or niobium layer.

13. The photovoltaic cell of claim 1, wherein said first layer is substantially free of molybdenum.

14. The photovoltaic cell of claim 1, wherein said second layer comprises at least one of molybdenum and chromium.

15. The photovoltaic cell of claim 1, wherein said first layer further comprises selenium or sulfur.

16. A method for forming a photovoltaic cell, comprising:
(a) providing, in a reaction space, a substrate comprising a first layer, wherein said substrate comprises a front side and a back side that is disposed away from said front side, and wherein said first layer comprises copper and indium;
(b) contacting said first layer with a source of selenium or sulfur, thereby converting said first layer to an absorber layer that is configured to generate electron/hole pairs upon exposure to electromagnetic radiation,
wherein a second layer comprising niobium or tantalum is formed adjacent to said back side of said substrate prior to contacting said first layer with said source of selenium or sulfur, and
wherein a third layer comprising molybdenum or tungsten is formed between said second layer and said substrate.

17. The method of claim 16, wherein, in (a), said first layer further comprises gallium, and wherein, in (b), (i) said substrate and said first layer are contacted with said source of selenium, and (ii) said absorber layer comprises copper indium gallium di-selenide.

18. The method of claim 16, wherein, in (b), (i) said substrate and said first layer are contacted with said source of sulfur, and (ii) said absorber layer comprises copper indium sulfide.

19. The method of claim 16, wherein said second layer is formed adjacent to said back side prior to (b).

20. The method of claim 16, wherein said second layer is substantially free of molybdenum.

21. The method of claim 16, further comprising forming a window layer adjacent to said absorber layer.

22. The method of claim 21, further comprising forming an electrically non-conductive metal oxide layer adjacent to said window layer.

23. The method of claim 22, further comprising forming a transparent metal oxide layer adjacent to said electrically non-conductive metal oxide layer.

24. The method of claim 21, wherein said window layer comprises cadmium and sulfur.

25. The method of claim 21, wherein said window layer is n-type.

26. The method of claim 16, wherein said CIGS is p-type.

27. The method of claim 16, wherein said absorber layer further comprises sodium.

28. The method of claim 16, wherein said substrate comprises stainless steel or aluminum.

29. The method of claim 16, further comprising forming a barrier layer adjacent to said substrate prior to forming said first layer.

30. The method of claim 29, wherein said barrier layer comprises chromium or titanium.

31. The method of claim 29, further comprising forming a molybdenum layer adjacent to said barrier layer, a chromium or niobium layer adjacent to said molybdenum layer, and a molybdenum layer adjacent to said chromium or niobium layer.

32. The method of claim 29, further comprising forming another barrier layer adjacent to said barrier layer, wherein said another barrier layer comprises molybdenum or niobium.

33. The method of claim 29, further comprising forming a third layer comprising at least one of molybdenum and chromium adjacent to said back side of said substrate, and forming said second layer adjacent to said third layer.

34. The method of claim 16, wherein forming said first layer further comprises exposing said substrate to a source of copper, a source of indium and a source of gallium.

35. The method of claim 16, wherein said third layer is formed prior to said second layer.

36. The method of claim 35, further comprising, between (a) and (b), contacting said third layer with a source of niobium to form said second layer comprising niobium adjacent to said third layer.

37. The method of claim 16, wherein (a) further comprises forming said first layer adjacent to said front side of said substrate.

38. The method of claim 16, wherein contacting said first layer with said source of selenium or sulfur deposits selenium or sulfur in said second layer.

39. A photovoltaic cell, comprising:
a protective layer, wherein said protective layer comprises an electrically conductive material;
a substrate adjacent to said protective layer;
a barrier layer adjacent to said substrate, wherein said barrier layer is formed of an electrically conductive material;
an absorber layer adjacent to said one or more electrically conductive layers, wherein said absorber layer comprises copper and indium, and wherein said absorber layer is configured to generate electron/hole pairs upon exposure of said absorber layer to electromagnetic radiation;
an optically transparent window layer adjacent to said absorber layer;
an electrically non-conductive metal oxide layer adjacent to said window layer; and
a transparent metal oxide layer adjacent to said electrically non-conductive metal oxide layer.

40. The photovoltaic cell of claim 39, wherein said protective layer comprises one or more of a metal carbide, metal boride, metal silicide or metal nitride.

41. The photovoltaic cell of claim 39, wherein said protective layer comprises one or more of titanium, tungsten and molybdenum.

42. The photovoltaic cell of claim 41, wherein said protective layer comprises one or more of titanium diboride, tungsten carbide, titanium nitride and molybdenum disilicide.

43. The photovoltaic cell of claim 39, wherein said window layer comprises cadmium and sulfur.

44. The photovoltaic cell of claim 39, wherein said window layer comprises zinc and sulfur.

45. The photovoltaic cell of claim 39, wherein said window layer is n-type.

46. The photovoltaic cell of claim 39, wherein said absorber is p-type.

47. The photovoltaic cell of claim 39, wherein said absorber comprises copper indium gallium di-selenide.

48. The photovoltaic cell of claim 39, wherein said absorber layer further comprises sodium.

49. The photovoltaic cell of claim 39, wherein said protective layer is substantially non-reactive with selenium.

50. The photovoltaic cell of claim 39, wherein said substrate comprises stainless steel or aluminum.

51. The photovoltaic cell of claim 39, further comprising an adhesion promoting layer between said protective layer and said substrate, wherein said adhesion promoting layer is configured to promote adhesion between said protective layer and said substrate.

52. The photovoltaic cell of claim 51, wherein said adhesion promoting layer comprises one or more of chromium, titanium and molybdenum.

53. The photovoltaic cell of claim 39, wherein said barrier layer comprises chromium or titanium.

54. The photovoltaic cell of claim 53, further comprising, between said barrier layer and said absorber layer, a molybdenum layer adjacent to said barrier layer, a chromium or niobium layer adjacent to said molybdenum layer, and a molybdenum layer adjacent to said chromium or niobium layer.

55. The photovoltaic cell of claim 39, further comprising another barrier layer adjacent to said barrier layer, wherein said another barrier layer comprises molybdenum or niobium.

56. The photovoltaic cell of claim 39, wherein said absorber layer comprises multiple layers of a photoactive material.

57. The photovoltaic cell of claim 39, wherein said electrically non-conductive layer comprises aluminum zinc oxide.

58. The photovoltaic cell of claim 39, wherein said transparent metal oxide layer comprises zinc oxide.
